(19) United States
(12) Patent Application Publication
(10) Pub. No.: US 2022/0003352 A1
(43) Pub. Date: Jan. 6, 2022

(54) SYSTEM AND METHOD TO DETECT AN INLINE TOOL IN A PIPE

(71) Applicant: Quest Integrity Group, LLC, Sugar Land, TX (US)

(72) Inventors: Petrus Willem VAN ANDEL, Sugar Land, TX (US); Robert Victor DE LORENZO, Sugar Land, TX (US)

(21) Appl. No.: 17/292,365

(22) PCT Filed: Nov. 7, 2019
(86) PCT No.: PCT/US19/60302

§ 371 Date: May 7, 2021

Related U.S. Application Data
(60) Provisional application No. 62/757,396, filed on Nov. 8, 2018.

(51) Int. Cl. F16L 55/48; G01V 3/08

(52) U.S. Cl. CPC F16L 55/48; G01V 3/081

(57) ABSTRACT

A system and method to detecting an inline tool traveling in a pipe. A tool magnet is affixed to the inline tool. A first magnetic sensor and a second magnetic sensor are longitudinally spaced from one another and disposed outside of the pipe, detecting a first magnetic field originating from the tool magnet with the first magnetic sensor and the second magnetic sensor as the inline tool travels through the pipe and proximate each of the first magnetic sensor and the second magnetic sensor. The system identifies the first magnetic field as originating from the tool magnet and detects a passage of the inline tool in the pipe based on identifying the first magnetic field as originating from the tool magnet.

### CROSS-REFERENCE TO RELATED APPLICATIONS

This application claims priority to U.S. Provisional Patent Application Ser. No. 62/757,396, filed Nov. 8, 2018, entitled “MAGNETIC PIG DETECTION,” which is incorporated herein by reference.

### FIELD OF DISCLOSURE

In general, the disclosure describes a system and methodology for detecting inline tool passage in a pipe using magnetic sensors.

### BACKGROUND OF INVENTION

Pigging of pipes or pipelines is performed to remove internal fouling, to inspect for defects in a pipe or to map the geographic location of the pipe. Pigging is done by pumping an inline tool, i.e. a pig, through a pipe. Intelligent pigs have sensors that can record information on the condition of the pipe.

One example use of pigs is in cleaning fired heaters that are used in industries such as power and oil and gas. Fired heaters are typically insulated enclosures that use heat created by the combustion of fuels to heat fluids contained within coils, tubes, pipes, or the like. The type of fired heater is generally described by the structural configuration, the radiant tube coil configuration and the burner arrangement.

Over time, the internal coils/tubes/pipes of the fired heater become internally fouled with coke. Coke is ash made of carbon fragments that lays down and coats the interior of the coils/tubes/pipes. Coke deposits drop out of the process stream if/when the stream gets too hot and starts to thermally degrade. Decoking is the industry term used to describe the process of removing coke or other types of internal fouling from a fired heater's inner coils/tubes/pipes. Presently, decoking is done by conveying cleaning pigs through the coils/tubes/pipes.

Whether in cleaning fired heaters or cleaning or inspecting other pipes, tubes or pipelines, a pig may get stuck somewhere in the pipe. Accordingly, it is important to be able to detect whether a pig has passed though one or more locations of the pipe. Various pig passage detectors, also called pig signalers, have been developed. These instruments can be based on non-intrusive sensors such as: ultrasonic, magnetic, acoustic, or radioactive detectors.

This present disclosure relates to improvements of magnetic sensors used to detect pig passage. In prior magnetic systems, a magnet is attached to the pig and a magnetic sensor can pick up the magnetic field caused by a moving pig. However, the reliability of the passage detection is not high in the case of a steel pipe which strongly attenuates the magnetic field. Highly sensitive magnetic sensors can be used to detect the weak field, but these highly sensitive magnetic sensors pick up any small magnetic field disturbance. These “false triggers” make the detection of a pig passage unreliable.

What is needed, is a more reliable method and system to detect the location of the pig while excluding false triggers.

### SUMMARY

This summary is provided to introduce a selection of concepts that are further described below in the detailed description. However, many modifications are possible without materially departing from the teachings of this disclosure. Accordingly, such modifications are intended to be included within the scope of this disclosure as defined in the claims. This summary is not intended to identify key or essential features of the claimed subject matter, nor is it intended to be used as an aid in limited the scope of the claimed subject matter.

An embodiment of the present disclosure provides a method for detecting an inline tool traveling in a pipe. The method includes affixing a tool magnet to the inline tool, providing a first magnetic sensor and a second magnetic sensor longitudinally spaced from one another and disposed outside of the pipe, detecting a first magnetic field originating from the tool magnet with the first magnetic sensor and the second magnetic sensor as the inline tool travels through the pipe and proximate each of the first magnetic sensor and the second magnetic sensor, identifying the first magnetic field as originating from the tool magnet, and detecting a passage of the inline tool in the pipe based on identifying the first magnetic field as originating from the tool magnet.

Another embodiment of the present disclosure provides a detection system for detecting an inline tool having a tool magnet and traveling in a pipe. The detection system includes a first magnetic sensor and a second magnetic sensor longitudinally spaced from one another and disposed outside of the pipe. The first magnetic sensor and the second magnetic sensor are configured to generate a set of output signals based on detecting a first magnetic field originating from the tool magnet as the inline tool travels through the pipe and proximate each of the first magnetic sensor and the second magnetic sensor. A processor is configured to analyze the set of output signals from the magnetic sensors to identify the first magnetic field as originating from the tool magnet and to detect a passage of the inline tool in the pipe based on identifying the first magnetic field as originating from the tool magnet. A display is configured to display a visual display indicative of the processor detecting the passage of the inline tool in the pipe as the inline tool travels in the pipe.

Another embodiment of the present disclosure provides a method for detecting an inline tool having a tool magnet and traveling in a pipe. The method includes providing a first magnetic sensor and a second magnetic sensor longitudinally spaced from one another and disposed outside of the pipe, detecting a first magnetic field from a first magnetic source with at least one of the first magnetic sensor and the second magnetic sensor, detecting a second magnetic field from a second magnetic source with at least one of the first magnetic sensor and the second magnetic sensor, identifying an inside pipe location for the first magnetic source, identifying an outside pipe location for the second magnetic source, detecting a passage of the inline tool in the pipe based on identifying the inside pipe location for the first magnetic source, and detecting a false passage trigger based on identifying the outside pipe location for the second magnetic source.

### BRIEF DESCRIPTION OF THE FIGURES

Certain embodiments of the disclosure will hereafter be described with reference to the accompanying drawings, wherein like reference numerals denote like elements. It is emphasized that, in accordance with standard practice in the industry, various features are not drawn to scale. In fact, the dimensions of various features may be arbitrarily increased or reduced for clarity of discussion. It should be understood, however, that the accompanying figures illustrate the various implementations described herein and are not meant to limit the scope of various technologies described herein, and:

FIG. 1 is a schematic of a detection system showing a first magnetic sensor and a second magnetic sensor positioned above a pipe shown in cross-section, an inline tool affixed with a tool magnet, and a computer coupled to the magnetic sensors in accordance with embodiments of the present disclosure;

FIG. 2 is a schematic illustrating a magnetic field vector having a Bx component, a By component, and a Bz component for a magnetic field detected by a magnetic sensor;

FIG. 3 is a schematic showing a first magnetic sensor positioned above the pipe shown in cross-section and an inline tool affixed with a tool magnet positioned in a first magnet orientation in accordance with embodiments of the present disclosure;

FIG. 4A is a graph showing the change in magnetic field for the Bx component measured by the first magnetic sensor as the tool magnet in the first magnet orientation passes by the first magnetic sensor moving in a positive X direction;

FIG. 4B is a graph showing the change in magnetic field for the By component measured by the first magnetic sensor as the tool magnet in the first magnet orientation passes by the first magnetic sensor moving in the positive X direction;

FIG. 5A is a graph showing the change in magnetic field for the Bx component measured by the first magnetic sensor as the tool magnet in the first magnet orientation passes by the first magnetic sensor moving in the negative X direction;

FIG. 5B is a graph showing the change in magnetic field for the By component measured by the first magnetic sensor as the tool magnet in the first magnet orientation passes by the first magnetic sensor moving in the negative X direction;

FIG. 6 is a schematic showing a first magnetic sensor positioned above the pipe shown in cross-section and an inline tool affixed with a tool magnet positioned in a second magnet orientation in accordance with embodiments of the present disclosure;

FIG. 7A is a graph showing the change in magnetic field for the Bx component measured by the first magnetic sensor as the tool magnet in the second magnet orientation passes by the first magnetic sensor moving in the positive X direction;

FIG. 7B is a graph showing the change in magnetic field for the By component measured by the first magnetic sensor as the tool magnet in the second magnet orientation passes by the first magnetic sensor moving in the positive X direction;

FIG. 8A is a graph showing the change in magnetic field for the Bx component measured by the first magnetic sensor as the tool magnet in the second magnet orientation passes by the first magnetic sensor moving in the negative X direction;

FIG. 8B is a graph showing the change in magnetic field for the By component measured by the first magnetic sensor as the tool magnet in the second magnet orientation passes by the first magnetic sensor moving in the negative X direction;

FIG. 9 shows an external magnet moving in a positive X direction outside the pipe and by the first magnetic sensor to create a disturbing magnetic field originating from outside the pipe in accordance with embodiments of the present disclosure;

FIG. 10 is a flowchart of an exemplary method in accordance with embodiments of the present disclosure; and

FIG. 11 is a flowchart of an alternative exemplary method in accordance with embodiments of the present disclosure

### DETAILED DESCRIPTION

In the following description, numerous details are set forth to provide an understanding of some embodiments of the present disclosure. It is to be understood that the following disclosure provides many different embodiments, or examples, for implementing different features of various embodiments. Specific examples of components and arrangements are described below to simplify the disclosure. These are, of course, merely examples and are not intended to be limiting. In addition, the disclosure may repeat reference numerals and/or letters in the various examples. This repetition is for the purpose of simplicity and clarity and does not in itself dictate a relationship between the various embodiments and/or configurations discussed. However, it will be understood by those of ordinary skill in the art that the system and/or methodology may be practiced without these details and that numerous variations or modifications from the described embodiments are possible. This description is not to be taken in a limiting sense, but rather made merely for the purpose of describing general principles of the implementations. The scope of the described implementations should be ascertained with reference to the issued claims.

As used herein, the terms “connect”, “connection”, “connected”, “in connection with”, and “connecting” are used to mean “in direct connection with” or “in connection with via one or more elements”; and the term “set” is used to mean “one element” or “more than one element”. Further, the terms “couple”, “coupling”, “coupled”, “coupled together”, and “coupled with” are used to mean “directly coupled together” or “coupled together via one or more elements”. As used herein, the terms “up” and “down”; “upper” and “lower”; “top” and “bottom”; and other like terms indicating relative positions to a given point or element are utilized to more clearly describe some elements. As used herein, the terms “coils”, “pipes”, and “tubes” are used individually or in combination to mean the internal fluid carrying elements of a fired heater.

The present disclosure generally relates to a system and method of using magnetic sensors to detect an inline tool, such as a pig, passing through a pipe. Embodiments of the present disclosure provide a system with two magnetic sensors placed along the pipe. In some embodiments, there may be more than two magnetic sensors. As will be described herein, signals coming from the two magnetic sensors are analyzed to discriminate between the magnetic field coming from the inside of the pipe and a disturbing magnetic field originating from an external source that is located somewhere outside of the pipe. This improves the reliability of an inline tool passage detection by excluding any false triggers. Embodiments of the present disclosure also enable determination of the direction of inline tool travel.

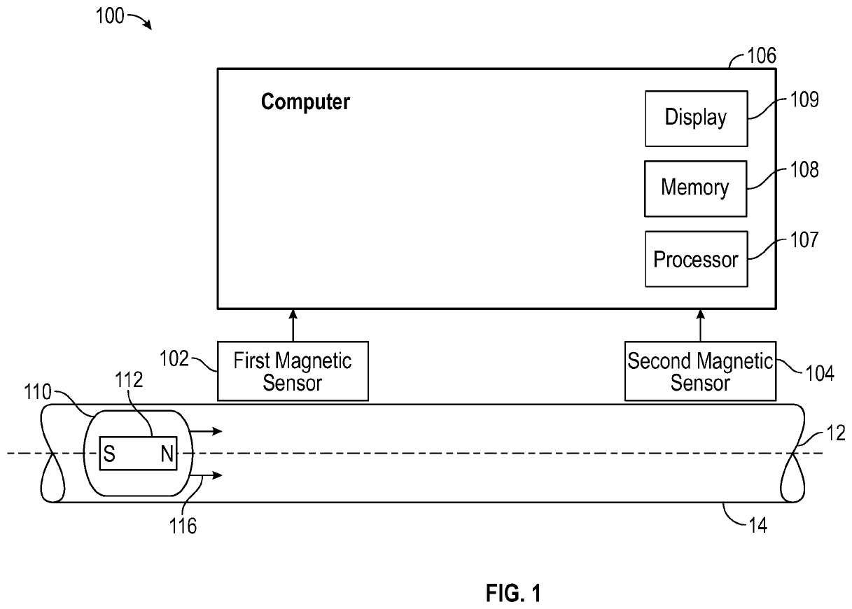

Referring to FIG. 1, an embodiment of a detection system 100 according to the present disclosure is shown. Detection system 100 includes a first magnetic sensor 102, a second magnetic sensor 104, a computer 106, an inline tool 110, and a tool magnet 112. First magnetic sensor 102 and the second magnetic sensor 104 are placed at different positions along a pipe 12. Tool magnet 112 is affixed to the inline tool 110 and has a magnetic field that can be detected by the magnetic sensors 102, 104 as the inline tool 110 passes by the magnetic sensors 102, 104.

Magnetic sensors 102, 104 are placed outside of the pipe 12. Magnetic sensors 102, 104 may be placed directly on a pipe outer surface 14, as illustrated in FIG. 1, or may be placed at a certain distance from the pipe 12. In some embodiments, magnetic sensors 102, 104 may be disposed outside the pipe 12 so that each of the magnetic sensors 102, 104 is approximately the same radial distance from the tool magnet 112 as the tool magnet 112 passes by each magnetic sensor 102, 104, for example when each of the magnetic sensors 102, 104 is mounted on a straight section of the pipe 12 as shown in FIG. 1. Magnetic sensors 102, 104 are longitudinally spaced from one another and positioned proximate the pipe 12 to be able to measure the magnetic signal from the magnet 12 as the inline tool 110 travels through the pipe 12 and by the magnetic sensors 102, 104. The longitudinal distance between the magnetic sensors 102, 104 may be less than a pipe diameter or may be up to several pipe diameters. The longitudinal distance may be measured along a line parallel to a centerline 16 of the pipe 12. In some embodiments, more than two magnetic sensors may be used and remain within the purview of the present disclosure. In some embodiments, magnetic sensors 102, 104 may be substantially identical.

Inline tool 110 is configured to be disposed inside of the pipe 12 and to travel through the pipe 12. As shown in FIG. 1, inline tool 110 may be embodied by a pig that may be configured to remove internal fouling, to inspect for defects in the pipe, or to map the geographic location of the pipe 12. Inline tool 110 may travel in either direction in the pipe 12. Arrows 116 in FIG. 1 depict inline tool 110 traveling in a direction in the pipe 12 to first pass by first magnetic sensor 102 and to then pass by second magnetic sensor 104. In some embodiments, inline tool 110 may be pumped through the pipe 12 in either direction. Tool magnet 112 may be affixed to the inline tool 110 at a central location of the inline tool 110 so that the tool magnet 112 travels along the centerline 16 of the pipe 12 when passing by the magnetic sensors 102, 104.

Magnetic sensors 102, 104 are configured to detect and measure the magnetic field of the tool magnet 112 as the tool magnet 112 passes by each of the magnetic sensors 102, 104. First magnetic sensor 102 generates first output signals based on the measurement of the magnetic field of the tool magnet 112 passing by the first magnetic sensor 102. Second magnetic sensor 104 generates second output signals based on the measurement of the magnetic field of the tool magnet 112 passing by the second magnetic sensor 104. Magnetic sensors 102, 104 are coupled to the computer 106 and the first output signals and the second output signals may be sent to the computer 106. Embodiments of the detection system 100 may include wired, wireless, or other connections to couple the magnetic sensors 102, 104 to the computer 106. Magnetic sensors 102, 104 may transmit first output signals and second output signals to the computer 106. Embodiments of computer 106 may include a processor 107, a memory 108, and a display 109 for processing, storing, and displaying information based on the first output signals and the second output signals.

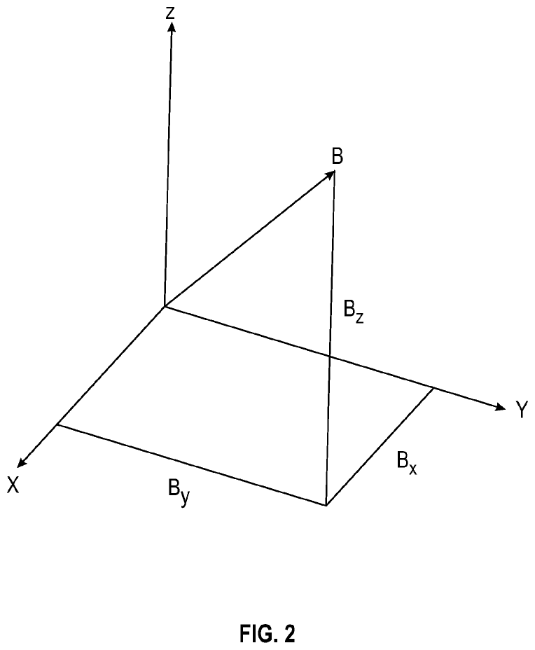

FIG. 2 illustrates the magnetic field of a magnet, such as the tool magnet 112. The magnetic field is represented as a magnetic field vector B which has three orthogonal magnetic field components: Bₓ field component, B_{y} field component, and B_{z} field component. The three orthogonal field components may be referred to as a first field component, a second field component, and a third field component. Magnetic sensors 102, 104 each may be composed of three independent sensors that measure the magnetic field along three orthogonal axes X, Y, and Z. This enables measurement of the amplitude and direction of the field vector B. Magnetic sensors 102, 104 are mounted at a known orientation with respect to the pipe 12. The orientation of the sensor axes with respect to the pipe and the position of the sensors can differ from the above, yet this can be corrected by applying coordinate transformations and thus the method also works for different sensor orientation and position.

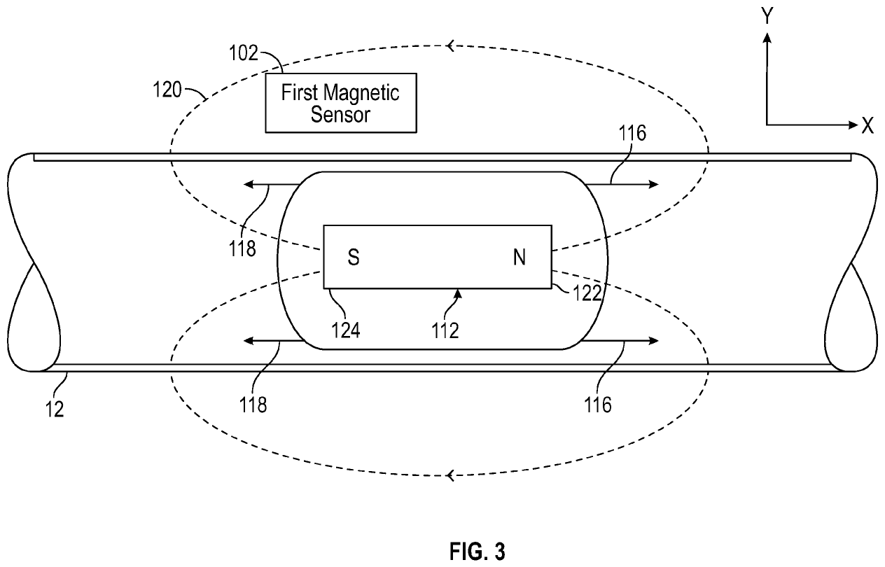

Referring to FIG. 3, the inline tool 110 is shown traveling through the pipe 12 and at least partially below the first magnetic sensor 102. Inline tool 110 also travels through the pipe 12 and by the second magnetic sensor 104, shown in FIG. 1. Magnetic sensors 102, 104 operate in a similar manner to measure the magnetic field of the tool magnet 112 that passes by each of the magnetic sensors 102, 104. FIG. 3 shows the first magnetic sensor 102 to illustrate and for use in describing the operation of both the first magnetic sensor 102 and the second magnetic sensor 104. The magnetic field measurements can be done by the magnetic sensors 102, 104 with arbitrary orientation of the sensor axes with respect to the pipe orientation. For convenience only, the orientation of the sensor axes is defined as shown in FIG. 3. The Y axis is taken parallel to the direction that is normal to the pipe surface and the X axis is parallel to the pipe surface.

As shown in FIG. 3, the tool magnet 112 is attached to the inline tool 110 by which the tool magnet 112 is kept approximately in the middle of the pipe 12. The tool magnet 112 has a first magnet orientation in FIG. 3 where the north pole 122 is oriented towards a first portion of the inline tool 110 and the south pole 124 is oriented towards an opposite, second portion of the inline tool 110. The dotted lines 120 represent magnetic field lines that leave the tool magnet 112 at the north pole 122 and reenter at the south pole 124. The tangent to the field line gives the direction of the magnetic field vector B. Inline tool 110 with the affixed tool magnet 112 may travel in the positive X direction, as depicted by arrows 116, or the negative X direction, as depicted by arrows 118.

When the tool magnet 112 is in the first magnet orientation shown in FIG. 3 and moving in the positive X direction and by the first magnetic sensor 102, the first magnetic sensor 102 is first influenced by the north pole 122 and later by the south pole 124. When the tool magnet 112 is in the first magnet orientation shown in FIG. 3 and moving in the negative X direction by the first magnetic sensor 102, the first magnetic sensor 102 is first influenced by the south pole 124 and later by the north pole 122. The magnet orientation of the tool magnet 112 influences the magnetic component signals measured by the first magnetic sensor 102, as discussed below.

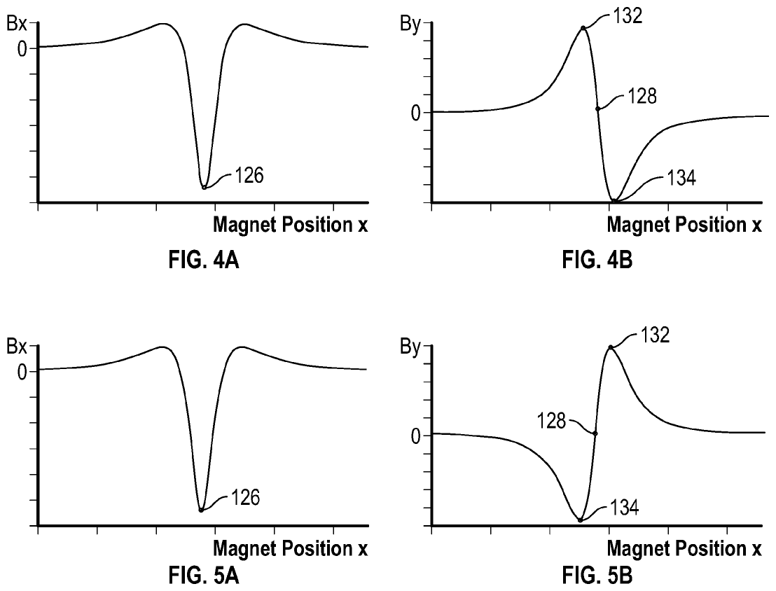

Referring to FIGS. 4A and 4B, graphs are shown of the Bx component signal and the By component signal, respectively, measured by the first magnetic sensor 102 when the tool magnet 112 affixed to the inline tool 110 in the first magnet orientation passes by the first magnetic sensor 102 in the positive X direction, as depicted by arrows 116 in FIG. 3. More specifically, FIG. 4A shows the graph of the change in the Bx component of the magnetic field and FIG. 4B shows the graph of the change in the By component of the magnetic field. The lowest dip point 126 in the Bx component signal is measured at the tool magnet position where the By component signal has a zero crossing 128.

As the tool magnet 112 moves by the first magnetic sensor, the By component signal has a highest peak point 132 and a lowest dip point 134, as shown in FIG. 4B. When the tool magnet 112 is in the first magnet orientation and moving in a positive X direction, the sequence of the lowest dip point 134 and highest peak point 132 for the B_{y} component signal is first the highest peak point 132 and second the lowest dip point 134. The sequential order of first the peak point 132 and the second the dip point 134 of the By component signal may be referred to as a peak and dip sequence. The magnetic field in the Z direction is zero at the position of the first magnetic sensor 102.

Referring to FIGS. 5A and 5B, graphs are shown of the Bx component signal and the By component signal, respectively, of the magnetic field measured by the first magnetic sensor 102 when the tool magnet 112 affixed to the inline tool 110 passes underneath the first magnetic sensor 102 in the negative X direction, as depicted by arrows 118 in FIG. 3. More specifically, FIG. 5A shows the graph of the change in the Bx component of the magnetic field and FIG. 5B shows the graph of the change in the By component of the magnetic field. The lowest dip point 126 in the Bx component signal is measured at the magnet position where the By component signal has a zero crossing 128.

As the tool magnet 112 moves by the first magnetic sensor in the negative X direction, the By component signal has a lowest dip point 134 and a highest peak point 132. When the tool magnet 112 is in the first magnet orientation and moving in a negative X direction, the sequence for the By component signal is first the lowest dip point 134 and second the highest peak point 132. The sequential order of first the lowest dip point 134 and second the highest peak point 132 for the By component signal may be referred to as a dip and peak sequence. The sequence of the highest peak point and the lowest dip point in the By component signal reverses based on whether the tool magnet 112 affixed to the inline tool 110 in the first magnet orientation moves in the positive X direction or the negative Y direction by the first magnetic sensor 102. The Bx component signal does not change when reversing the inline tool movement direction between the positive X direction and the negative X direction. The magnetic field in the Z direction is zero at the position of the first magnetic sensor 102.

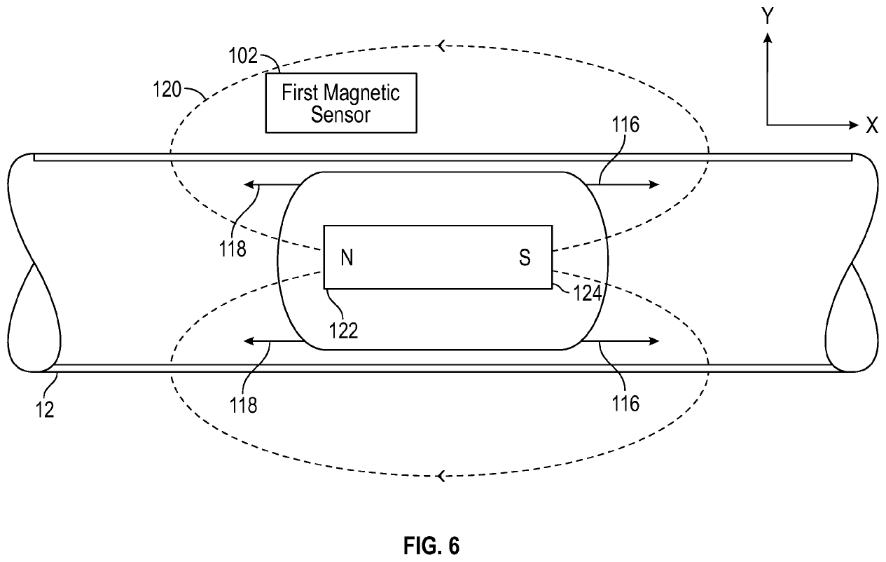

Referring to FIG. 6, the orientation of the magnet may be reversed, i.e. the north pole 122 and south pole 124 are interchanged, to position the tool magnet 112 affixed to the inline tool 110 in a second magnet orientation. In some embodiments, the inline tool 110 may be placed in the pipe 12 with the inline tool with the affixed tool magnet 112 in a selected magnet orientation with respect to the pipe 12 and the direction of travel of the inline tool 110 in the pipe. The selected magnet orientation of affixed tool magnet for the inline tool 110 placed in the pipe may be stored in the memory 108 to be used in detecting the passage of the inline tool 110 and detecting a false passage trigger. In some embodiments, the inline tool 110 may rotate within the pipe 12 when traveling in the pipe 12.

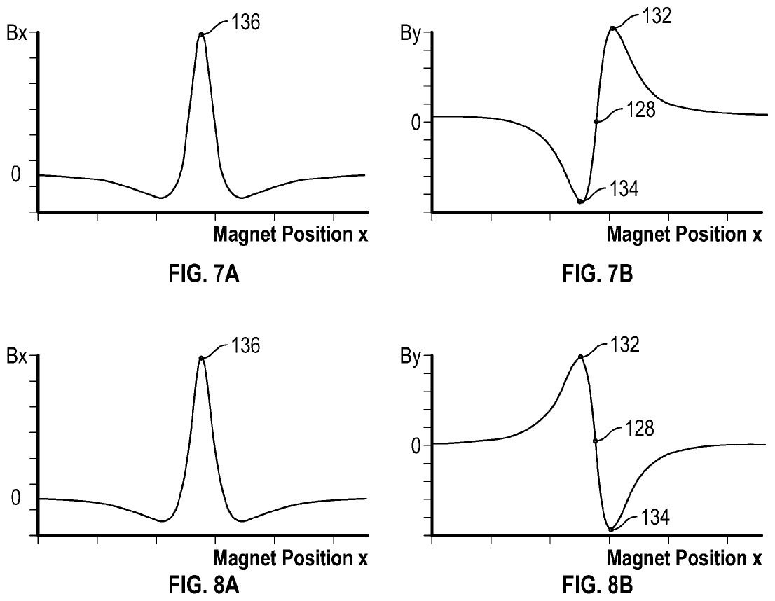

Referring to FIGS. 7A and 7B, graphs are shown of the Bx component signal and the By component signal, respectively, of the magnetic field measured by the first magnetic sensor 102 when the tool magnet 112 in the second magnet orientation passes underneath the first magnetic sensor 102 in the positive X direction. More specifically, FIG. 7A shows the graph of the change in the magnetic field for the Bx component and FIG. 7B shows the graph of the change for the By component.

Tool magnet 112 in the second magnet orientation will result in a change in polarity of the measured Bx component signal, as shown in FIG. 7A, compared to the Bx component signal for the tool magnet 112 in the first magnet orientation, as shown in FIG. 4A. A highest peak point 136 in the Bx magnetic field signal for the tool magnet 112 in the second magnet orientation is measured at the magnet position where the By magnetic field signal has a zero crossing 128.

As the tool magnet 112 in the second magnet orientation moves by the first magnetic sensor 102 in the positive X direction, the By component signal has a lowest dip point 134 and a highest peak point 132, as shown in FIG. 7B. When the tool magnet 112 is in the second magnet orientation and moving in a positive X direction, the sequence for the By component signal is first the lowest dip point 134 and second the highest peak point 132, also referred to as a dip and peak sequence.

The tool magnet 112 affixed to the inline tool 110 in the second magnet orientation, as shown in FIG. 6, also may move by the first magnetic sensor 102 in a negative X direction.

Referring to FIGS. 8A and 8B, graphs are shown for the Bx component signal and the By component signal, respectively, of the magnetic field of the tool magnet 112 in the second magnet orientation moving in a negative X direction. More specifically, FIG. 8A shows the graph of the change in the Bx component and FIG. 8B shows the graph of the change for the By component. Highest peak point 136 in the Bx magnetic field signal is measured at the magnet position where the By magnetic field signal has a zero crossing 128.

As the tool magnet 112 in the second magnet orientation moves in the negative X direction, the By magnetic field signal has a highest peak point 132 and then a lowest dip point 134, also referred to as a peak and dip sequence. When the tool magnet 112 is in the second magnet orientation and moving in a negative X direction, the By component signal has a peak and dip sequence. The sequence of the highest peak point and the lowest dip point in the By component signal reverses based on whether the tool magnet 112 affixed to the inline tool 110 in the second magnet orientation moves in the positive X direction or the negative Y direction by the first magnetic sensor 102. The Bx component signal does not change when reversing movement direction of the tool magnet 112 affixed to the inline tool 110 between positive X direction and the negative X direction. The Bz component signal of the magnetic field is approximately zero at the position of the first magnetic sensor 102.

Changing the tool magnet 112 affixed to the inline tool 110 between the first magnet orientation and the second magnet orientation will result in a change in polarity of the measured Bₓ magnetic field signal, as shown by a comparison of FIG. 4A and FIG. 5A to FIGS. 7A and 8A.

Changing the tool magnet 112 affixed to the inline tool 110 between the first magnet orientation and the second magnet orientation will reverse the sequence of the peak 132 and the dip 134 in the B_{y} magnetic field signal for a tool magnet 112 moving in the same X direction. More specifically, the tool magnet 112 in the first magnet orientation and moving in the positive X direction has the peak and dip sequence, as shown in FIG. 4B, and the tool magnet 112 in the second magnet orientation and moving in the positive X direction has the dip and peak sequence, as shown in FIG. 7B. Tool magnet 112 in the first magnet orientation and moving in the negative X direction has the dip and peak sequence, as shown in FIG. 5B, and the tool magnet 112 in the second magnet orientation and moving in the negative X direction has the peak and dip sequence, as shown in FIG. 8B.

As described above, the magnetic signals measured by the magnetic sensors 102, 104 have certain signal characteristics based on the magnet orientation and the direction of the magnet motion. The signal characteristics may be used in determining the four different tool magnet movement and tool orientation combinations. The four different tool magnet movements and orientation combinations include the tool magnet 112 in a first magnet orientation and moving in a positive X direction, the tool magnet 112 in the first magnet orientation and moving in a negative X direction, the tool magnet 112 in the second magnet orientation and moving in a positive X direction, and the tool magnet 112 in the second magnet orientation and moving in the negative X direction.

The magnet in the first magnet orientation and moving in the positive X direction may be identified by a first combination of magnetic signal characteristics including the peak and dip sequence for the By component signal and the lowest dip 126 for the Bx component signal. The tool magnet 112 in the first magnet orientation and moving in the negative X direction may be identified by a second combination of magnetic signal characteristics including the dip and peak sequence for the By component signal and the lowest dip 126 for the Bx component signal. The tool magnet 112 in the second magnet orientation and moving in the positive X direction may be identified by a third combination of magnetic signal characteristics including the dip and peak sequence for the By component signal and the highest peak 136 for the Bx component signal. The tool magnet 112 in the second magnet orientation and moving in the negative X direction may be identified by a fourth combination of magnetic signal characteristics including the peak and dip sequence for the By component signal and the highest peak 136 for the Bx component signal.

Magnetic sensor 102 may measure a disturbing magnetic signal that is not generated by the tool magnet 112. For example, the disturbing magnetic signal may come from outside of the pipe. A disturbing magnetic signal may be generated by equipment, the environment, electrical currents or other external magnetic sources disposed outside of the pipe 12. The disturbing magnetic signal may have a combination of magnetic signal characteristics that are like one of the four combinations of magnetic signal characteristics for the tool magnet 112 affixed to the inline tool 110 and traveling in the pipe 12. This could potentially lead to a false detection, also referred to as a false passage trigger, of an inline tool passing through the pipe 12.

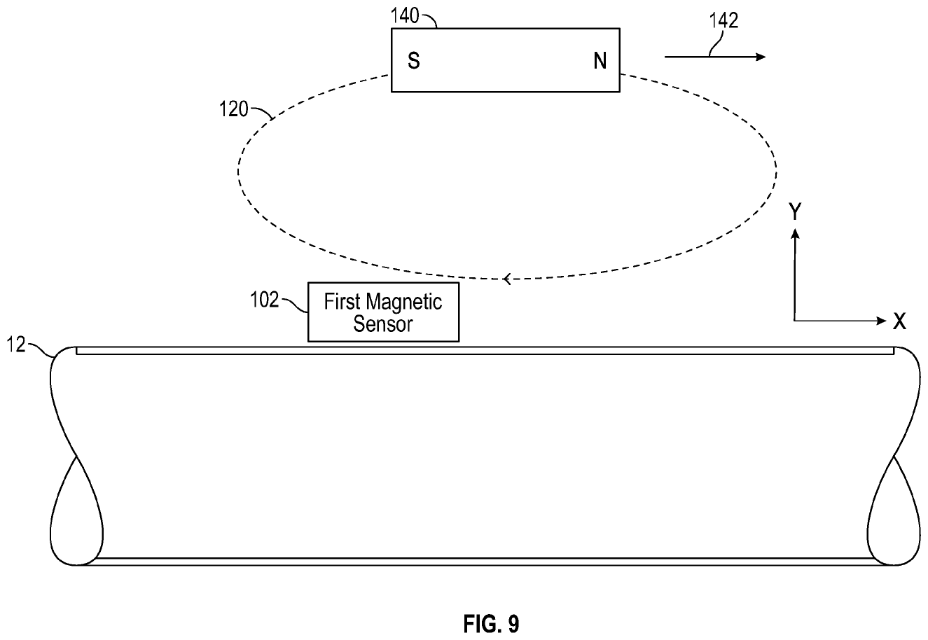

Referring to FIG. 9, a disturbing magnetic signal is simulated by an external magnet 140 moving above the magnetic sensor 102 in the first magnet orientation and moving in the positive X direction. Any external magnetic field disturbance including magnetic fields from electric currents can be simulated as a series of magnet dipole fields. The external magnet 140 shown in FIG. 8 will cause the magnetic sensor 102 to measure a disturbing magnetic signal that may have similarities or some similar characteristics to one of the magnetic signals generated by the tool magnet 112 traveling in the pipe 12 and measured by the first magnetic sensor 102. For example, the disturbing magnetic signal from the external magnet 140 in the first magnet orientation and traveling in the positive X direction potentially could be misinterpreted as originating from the tool magnet 112 in the first magnet orientation and traveling in a negative X direction. More specifically, the magnetic sensor 102 may measure a disturbing magnetic signal from the external magnetic source that has the second combination of magnetic signal characteristics as shown in FIGS. 5A and 5B, including the dip and peak sequence for the By component signal and the lowest dip 126 for the Bx component signal.

Embodiments of the present disclosure provide at least two magnetic sensors, such as magnetic sensors 102, 104, to avoid such misinterpretation. Using two magnetic sensors 102, 104 as shown in FIG. 1 results in measuring the same magnetic signals from the tool magnet 112 twice or an external magnetic source twice, only shifted in position. A multi-sensor magnet direction may be determined by identifying the magnet detection sequence for the first magnetic sensor 102 and the second magnetic sensor 104. For example, a first magnet detection sequence may occur where the first magnetic sensor 102 detects a magnetic field at a first time and then the second magnetic sensor 104 detects the magnetic field at a second time. The first magnet detection sequence for the magnetic sensors 102, 104 indicates that the multi-sensor magnet direction is in the positive X direction, or in other words the magnetic field is moving in a positive X direction. A second magnet detection sequence may occur where the second magnetic sensor 104 detects a magnetic field at a first time and then the first magnetic sensor 102 detects the magnetic field at a second time. The second magnet detection sequence for the magnetic sensors 102, 104 indicates that the multi-sensor magnet direction is in the negative X direction, or in other words the source of the magnetic field is moving in a negative X direction. Therefore, with two magnetic sensors 102, 104 a multi-sensor magnet direction may be determined for the magnetic field detected at different times by the magnetic sensors 102, 104. The multi-sensor magnet direction may be used as the actual movement direction, positive X direction or negative X direction, of the tool magnet 112 or the external magnet 140.

To determine whether the magnetic field detected by the magnetic sensors 102, 104 is generated from the tool magnet 112 or an external magnet 140, embodiments of the present disclosure use a combination of 1) the determination of the direction of magnet motion by identifying a magnetic detection sequence using the two magnetic sensors 102, 104, and 2) the determination of the magnet orientation and the direction of magnet motion through the use of a combination of magnetic signal characteristics measured by at least one of the two magnet sensors 102, 104, as described with respect to FIGS. 4A-B, 5A-B, 7A-B, and 8A-B. Embodiments of the present invention may use this method to identify disturbing magnetic signals to prevent a false detection of the passage in the pipe of the tool magnet 112 affixed to the inline tool 110.

For example, the detection system 100 may measure a magnetic field with at least one of the magnetic sensors 102, 104 having magnetic signal characteristics as shown in FIGS. 5A and 5B. These magnetic signal characteristics may be caused either by a tool magnet 112 affixed to the in-line tool 110 in the first magnet orientation and traveling in a negative X direction or by an external magnet 140 in the first magnet orientation and traveling in a positive X direction. Determining a positive X direction for the multi-sensor magnet direction indicates, in combination with the magnetic signal characteristics of FIGS. 5A and 5B, that the magnetic signals are from the external magnetic 140 located outside the pipe 12. Determining a negative X direction for the multi-sensor magnet direction indicates, in combination with the magnetic signal characteristics of FIGS. 5A and 5B, that the magnetic signals are from the tool magnet 112 located inside the pipe 12.

A second effect that helps to determine the position of a magnetic source of a magnetic field measured by the magnetic sensors 102, 104 in embodiments of the present disclosure results from the tool magnet 112 being approximately centered by the inline tool 110 in the middle of the pipe 12. As a result, the tool magnet 112 will therefore approximately follow the path of the centerline 16 of the pipe 12. Accordingly, the first magnetic sensor 102 and the second magnetic sensor 104 will measure approximately the same amplitude and wavelet form for the Bx component signal and B_{y} component signal if both magnetic sensors 102, 104 are at the same distance from the pipe surface and the tool magnet 112 that passes by the magnetic sensors 102, 104. A moving external magnet 140 with arbitrary path and arbitrary orientation will display amplitude and wavelet form deviations by which it can be recognized as an external magnet (i.e. false trigger).

A third effect that helps to determine the position of a magnetic source of a magnetic field measured by the magnetic sensors 102, 104 in embodiments of the present disclosure results from the tool magnet 112 being fixed to the inline tool 110 and the magnetic sensors 102, 104 oriented to measure the Bx magnetic component and the By magnetic component. As a result, the tool magnet 112 will therefore approximately follow the path of the centerline 16 of the pipe 12. Accordingly, the first magnetic sensor 102 and the second magnetic sensor 104 will measure approximately the same amplitude and wavelet form for the Bx component signal and By component signal, and approximately zero for the B_{z} magnetic component. An external magnetic source may not be oriented with respect to the magnetic sensors 102, 104 in the same manner as the tool magnet 112. Accordingly, the Bz magnetic component for a magnetic field from an external magnetic source may have a large amplitude compared to amplitude for the Bz component signal for the tool magnet 112. A measurement of the Bz component for a magnetic source by either of the magnetic sensors 102, 104 above a reference Bz component value or signal may be indicative of an external magnetic source generating the Bz component for the magnetic signal being measured. The reference Bz component value or signal may be approximately zero or the reference Bz component value or signal may have characteristics indicative of a magnetic field from a tool magnet and not a magnetic field from an external magnet.

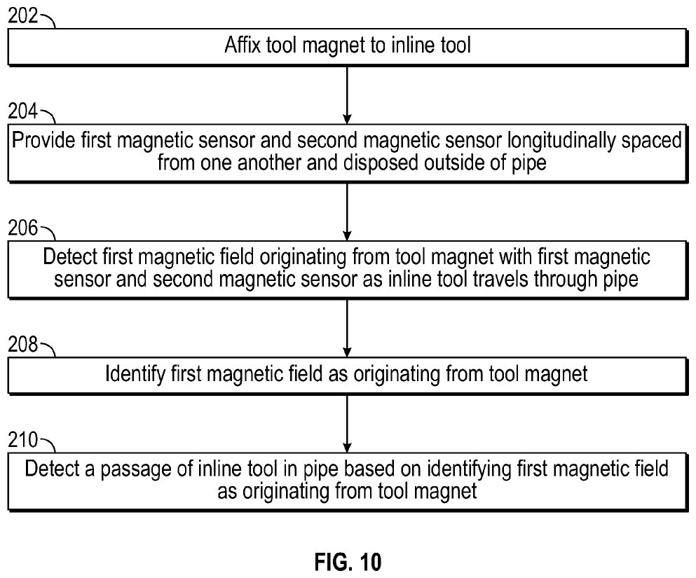

FIG. 10 is an exemplary flowchart of a method illustrating use of use of a detection system to detect an inline tool traveling in a pipe. A tool magnet is affixed to the inline tool (block 202). A first magnetic sensor and a second magnetic sensor is longitudinally spaced from one another and disposed outside of the pipe (block 204). A user of the detection system places the inline tool in the pipe. The inline tool may be moved through the pipe by pumping fluid through the pipe or in a conventional manner, and the inline tool will travel by the first magnetic sensor and the second magnetic sensor. The inline tool may be in a first magnet orientation or a second magnet orientation as the inline tool travels by the first magnetic sensor and the second magnetic sensor.

The first magnetic sensor and the second magnetic sensor detect a first magnetic field originating from the tool magnet as the inline tool travels through the pipe and proximate each of the first magnetic sensor and the second magnetic sensor (block 206). For example, the first magnetic sensor may first detect the first magnetic field at a first time as the inline tool approaches the first magnetic sensor in the pipe. The second magnetic sensor may detect the first magnetic field at a later second time as the inline tool approaches the second magnetic sensor. As the inline tool approaches and passes by each of the magnetic sensors, the first magnetic field from the tool magnet detected by the each of magnetic sensors changes, as shown and described with respect to 4A-B, 5A-B, 7A-B, and 8A-B.

The first magnetic sensor may generate first output signals based on changes in the first magnetic field detected by the first magnetic sensor as the tool magnet travels proximate the first magnetic sensor. The second magnetic sensor may generate second output signals based on changes in the first magnetic field detected by the second magnetic sensor as the tool magnet travels proximate the second magnetic sensor. The magnetic sensors may each transmit the first output signals and the second output signals to a computer for processing or analyzing information detected by the magnetic sensors. In some embodiments, the magnetic sensors may include one or more components of a computer for analyzing information detected by the magnetic sensors.

The detection system may be used to identify the first magnetic field as originating from the tool magnet (block 208). A computer coupled to the magnetic sensors may receive a set of output signals from the magnetic sensors that contain information on the detected first magnetic field from each of the magnetic sensors. The computer may use a processor to analyze the output signals received. A memory coupled to the processor may be used to store information for the detection system including information associated with the output signals, the locations and orientations of the magnetic sensors mounted proximate the pipe, and the magnet orientation of the inline tool placed in the pipe. By processing the output signals, the detected first magnetic field may be identified as originating from the tool magnet by determining the detected first magnetic field originates from an inside pipe location.

The detection system may be used to detect a passage of the inline tool in the pipe based on identifying the first magnetic field as originating from the tool magnet (block 210). The processor may generate a tool passage signal and transmit this information to a display. The display may output tool passage information indicative of an inline tool passing a known section or reference location in the pipe. The known section or reference location may be proximate one or both magnetic sensors, for example a known section or reference location disposed between the magnetic sensors.

The display may output the tool passage information as the inline tool travels through the pipe performing an operation for the pipe. The detection system may process and display information from the detection system, such as the tool passage information, in real time or near real time. An operator of the detection system may use the tool passage information to control the inline tool, such as the direction or speed of the inline tool traveling in the pipe, while the inline tool is being monitored by the detection system and during the operation being performed by the inline tool.

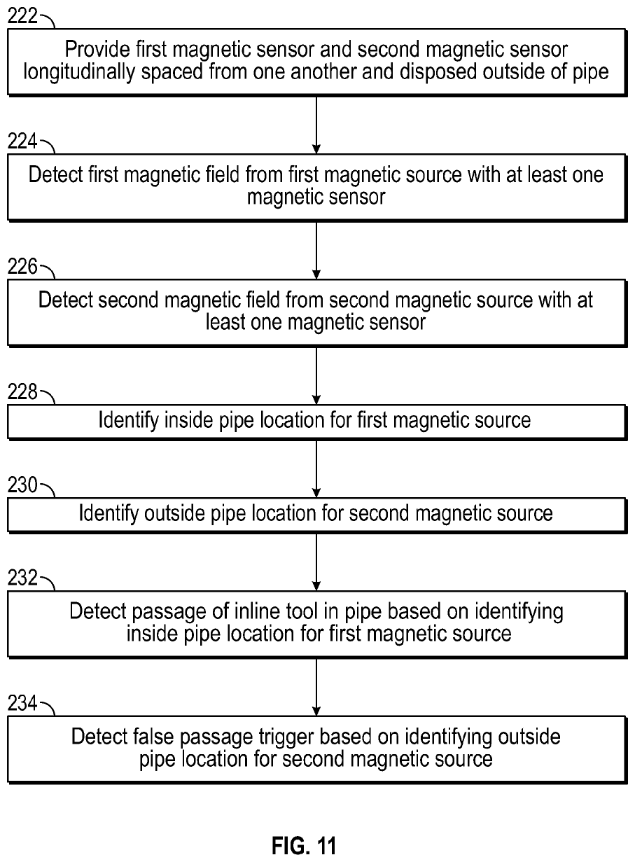

FIG. 11 is an exemplary flowchart of another method illustrating use of a detection system to detect an inline tool having a tool magnet and traveling in a pipe. The tool magnet is affixed to the inline tool. A first magnetic sensor and a second magnetic sensor is longitudinally spaced from one another and disposed outside of the pipe (block 222). The magnetic sensors may be disposed proximate the pipe, for example mounted on the pipe. A user of the detection system places the inline tool in the pipe, and the inline tool travels through the pipe. At least one of the magnetic sensors may be used to detect a first magnetic field from a first magnetic source (block 224). At least one of the magnetic sensors may be used to detect a second magnetic field from a second magnetic source (block 226). At least one of the magnetic sensors may generate first output signals based on changes in the first magnetic field detected by the first magnetic sensor as the tool magnet travels proximate the first magnetic sensor. At least one of the magnetic sensors may transmit output signals to a computer for processing or analyzing information detected by one or both magnetic sensors.

The detection system may be used to identify an inside pipe location for the first magnetic source (block 228) and may be used to identify an outside pipe location for the second magnetic source (block 230). The computer may use a processor to analyze the output signals received to process the output signals to identify the locations of the first magnetic source and the second magnetic source. A memory coupled to the processor may be used to store information for the detection system including information associated with the output signals, the locations and orientations of the magnetic sensors mounted proximate the pipe, and the magnet orientation of the inline tool placed in the pipe.

The detection system may be used to detect a passage of the inline tool in the pipe based on identifying the inside pipe location for the first magnetic source (block 232). The detection system may be used to detect a false passage trigger of the inline tool in the pipe based on identifying the outside pipe location for the second magnetic source (block 234). The false passage trigger is indicative of at least one of the magnetic sensors detecting an external magnetic field disturbance. For example, the processor may generate a false passage trigger signal and transmit this information to a display. In some embodiments, the display may output false passage information indicative of at least one of the magnetic sensors detecting the second magnetic field from the second magnetic source located outside of the pipe.

The forgoing provides a means to recognize magnetic disturbances that originate outside of the pipe. This reduces false indications from a tool magnet affixed to an inline tool, such as a pig, and makes the detection of the inline tool traveling through the pipe reliable.

Although a few embodiments of the disclosure have been described in detail above, those of ordinary skill in the art will readily appreciate that many modifications are possible without materially departing from the teachings of this disclosure. Accordingly, such modifications are intended to be included within the scope of this disclosure as defined in the claims. The scope of the invention should be determined only by the language of the claims that follow. The term “comprising” within the claims is intended to mean “including at least” such that the recited listing of elements in a claim are an open group. The terms “a,” “an” and other singular terms are intended to include the plural forms thereof unless specifically excluded. In the claims, means-plus-function clauses are intended to cover the structures described herein as performing the recited function and not only structural equivalents, but also equivalent structures. It is the express intention of the applicant not to invoke 35 U.S.C. § 112, paragraph 6 for any limitations of any of the claims herein, except for those in which the claim expressly uses the words “means for” together with an associated function.

1. A method for detecting an inline tool traveling in a pipe, the method comprising:
affixing a tool magnet to the inline tool;
providing a first magnetic sensor and a second magnetic sensor longitudinally spaced from one another and disposed outside of the pipe;
detecting a first magnetic field originating from the tool magnet with the first magnetic sensor and the second magnetic sensor as the inline tool travels through the pipe and proximate each of the first magnetic sensor and the second magnetic sensor;
identifying the first magnetic field as originating from the tool magnet; and
detecting a passage of the inline tool in the pipe based on identifying the first magnetic field as originating from the tool magnet.

2. The method of claim 1 wherein identifying the first magnetic field as originating from the tool magnet comprises determining the detected first magnetic field originates from an inside pipe location.

3. The method of claim 1 wherein identifying the first magnetic field as originating from the tool magnet comprises:
determining the tool magnet is traveling in a first direction based on changes in the first magnetic field as the tool magnet travels proximate at least one of the magnetic sensors; and
determining the tool magnet is traveling in the first direction in the pipe based on the first magnetic sensor detecting the tool magnet at a first time and the second magnetic sensor detecting the first magnetic field at a second time.

4. The method of claim 3 wherein identifying the first magnetic field as originating from the tool magnet further comprises determining a magnet orientation of the tool magnet based on changes in the first magnetic field as the tool magnet travels proximate at least one of the magnetic sensors.

5. The method of claim 4 wherein determining magnet orientation of the tool magnet comprises identifying a first signal characteristic of the first magnetic field indicative of magnet orientation, wherein the first signal characteristic is based on changes in the first magnetic field in a first magnetic field dimension.

6. The method of claim 5 wherein determining the tool magnet is traveling in a first direction based on changes in the first magnetic field comprises identifying a second signal characteristic of the first magnetic field indicative of a tool magnet direction, wherein the second signal characteristic is based on changes in the first magnetic field in a second magnetic field dimension, and wherein the first magnetic field dimension is orthogonal to the second magnetic field dimension.

7. The method of claim 6, wherein the first signal characteristic is either a lowest dip or highest peak in the first magnetic field in the first magnetic field dimension, and wherein the second signal characteristic is either a peak and dip sequence or a dip and peak sequence in the first magnetic field in the second magnetic field dimension.

8. The method of claim 1 wherein identifying the first magnetic field as originating from the tool magnet comprises:
generating via the first magnetic sensor a first output signal based on changes in the first magnetic field detected by the first magnetic sensor as the tool magnet travels proximate the first magnetic sensor;
generating via the second magnetic sensor a second output signal based on changes in the first magnetic field detected by the second magnetic sensor as the tool magnet travels proximate the second magnetic sensor; and
comparing the first output signal and the second output signal.

9. The method of claim 1, further comprising:
detecting a second magnetic field originating from an external magnetic source located outside of the pipe with at least one of the first magnetic sensor and the second magnetic sensor as the inline tool travels through the pipe;
identifying the second magnetic field as originating from the external magnetic source; and
detecting a false passage trigger based on identifying the second magnetic field as originating from the external magnetic source.

10. The method of claim 1, further comprising displaying a visual display indicative of detecting the passage of the inline tool in the pipe as the inline tool travels in the pipe.

11. A detection system for detecting an inline tool having a tool magnet and traveling in a pipe, the detection system comprising:
a first magnetic sensor and a second magnetic sensor longitudinally spaced from one another and disposed outside of the pipe, the first magnetic sensor and the second magnetic sensor are configured to generate a set of output signals based on detecting a first magnetic field originating from the tool magnet as the inline tool travels through the pipe and proximate each of the first magnetic sensor and the second magnetic sensor; and
a processor configured to analyze the set of output signals from the magnetic sensors to identify the first magnetic field as originating from the tool magnet and to detect a passage of the inline tool in the pipe based on identifying the first magnetic field as originating from the tool magnet; and
a display configured to display a visual display indicative of the processor detecting the passage of the inline tool in the pipe as the inline tool travels in the pipe.

12. The detection system of claim 11, wherein the processor is configured to identify the first magnetic field as originating from the tool magnet comprises determining the detected first magnetic field originates from an inside pipe location.

13. The detection system of claim 12 wherein identifying the first magnetic field as originating from the tool magnet comprises:
determining the tool magnet is traveling in a first direction based on changes in the first magnetic field as the tool magnet travels proximate at least one of the magnetic sensors; and
determining the tool magnet is traveling in the first direction in the pipe based on the first magnetic sensor detecting the tool magnet at a first time and the second magnetic sensor detecting the first magnetic field at a second time.

14. The detection system of claim 13 wherein identifying the first magnetic field as originating from the tool magnet further comprises determining a magnet orientation of the tool magnet based on changes in the first magnetic field as the tool magnet travels proximate at least one of the magnetic sensors.

15. The detection system of claim 14 wherein determining magnet orientation of the tool magnet comprises identifying a first signal characteristic of the first magnetic field indicative of magnet orientation, and wherein the first signal characteristic is based on changes in the first magnetic field in a first magnetic field dimension.

16. The detection system of claim 15 wherein determining the tool magnet is traveling in a first direction based on changes in the first magnetic field comprises identifying a second signal characteristic of the first magnetic field indicative of a tool magnet direction, wherein the second signal characteristic is based on changes in the first magnetic field in a second magnetic field dimension, and wherein the first magnetic field dimension is orthogonal to the second magnetic field dimension.

17. The detection system of claim 16 wherein the first signal characteristic is either a lowest dip or highest peak in the first magnetic field in the first magnetic field dimension, and wherein the second signal characteristic is either a peak and dip sequence or a dip and peak sequence in the first magnetic field in the second magnetic field dimension.

18. The detection system of claim 11 wherein the set of output signals comprise a first output signal and a second output signal, and wherein identifying the first magnetic field as originating from the tool magnet comprises:
generating via the first magnetic sensor the first output signal based on changes in the first magnetic field detected by the first magnetic sensor as the tool magnet travels proximate the first magnetic sensor;
generating via the second magnetic sensor the second output signal based on changes in the first magnetic field detected by the second magnetic sensor as the tool magnet travels proximate the second magnetic sensor; and
comparing the first output signal and the second output signal.

19. The detection system of claim 11, wherein at least one of the first magnetic sensor and the second magnetic sensor is configured to detect a second magnetic field originating from an external magnetic source located outside of the pipe as the inline tool travels through the pipe, wherein the processor is configured to identify the second magnetic field as originating from the external magnetic source, and wherein the processor is configured to detect a false passage trigger based on identifying the second magnetic field as originating from the external magnetic source.

20. A method for detecting an inline tool having a tool magnet and traveling in a pipe, the method comprising:
providing a first magnetic sensor and a second magnetic sensor longitudinally spaced from one another and disposed outside of the pipe;
detecting a first magnetic field from a first magnetic source with at least one of the first magnetic sensor and the second magnetic sensor;
detecting a second magnetic field from a second magnetic source with at least one of the first magnetic sensor and the second magnetic sensor;
identifying an inside pipe location for the first magnetic source;
identifying an outside pipe location for the second magnetic source;
detecting a passage of the inline tool in the pipe based on identifying the inside pipe location for the first magnetic source; and
detecting a false passage trigger based on identifying the outside pipe location for the second magnetic source.
